(19) United States
(12) Patent Application Publication
(10) Pub. No.: US 2022/0109441 A1
(43) Pub. Date: Apr. 7, 2022

(54) HIGH PERFORMANCE SWITCHES WITH NON-VOLATILE ADJUSTABLE THRESHOLD VOLTAGE

(71) Applicant: QUALCOMM Incorporated, San Diego, CA (US)

(72) Inventors: Sinan GOKTEPELI, Austin, TX (US); Ravi Pramod Kumar VEDULA, San Diego, CA (US); Sivakumar KUMARASAMY, San Diego, CA (US)

(21) Appl. No.: 17/061,314

(22) Filed: Oct. 1, 2020

(51) Int. Cl. H03K 17/687; H01L 27/06; H01L 21/8234

(52) U.S. Cl. CPC H03K 17/6871; H01L 21/8234; H01L 27/0629

(57) ABSTRACT

A radio frequency integrated circuit (RFIC) is described. The RFIC includes a field effect transistor (FET). The FET has a ferroelectric gate stack having a source region, a drain region, a body region, and a gate. The RFIC also includes a first resistor coupled between a first bias supply and the body region. The RFIC further includes a second resistor coupled between the gate and a second bias supply.

### TECHNICAL FIELD

The present disclosure generally relates to integrated circuits (ICs). More specifically, the present disclosure relates to a high performance switch with a nonvolatile, adjustable threshold voltage.

### BACKGROUND

Design challenges for mobile radio frequency (RF) transceivers include performance considerations for meeting 5G and future 6G transmission frequency specifications. These 5G/6G performance specifications mandate a substantial transmission frequency increase over current standards. Transistors are generally specified to operate at substantially higher frequencies for supporting communication enhancements, such as millimeter wave (mmWave) communications. These transistors may be switch transistors for implementing an RF switch of a mobile RF transceiver.

For example, high performance complementary metal oxide semiconductor (CMOS) RF switch technologies are currently manufactured to implement switch transistors. A series of switch transistors may be configured as an RF switch. Unfortunately, gate bias techniques for controlling the series of switch transistors may reduce a switching speed of the RF switch. The reduced switching speed of the RF switch may prohibit meeting 5G and future 6G transmission frequency specifications when implemented in a mobile RF transceiver.

### SUMMARY

A radio frequency integrated circuit (RFIC) is described. The RFIC includes a field effect transistor (FET). The FET has a ferroelectric gate stack having a source region, a drain region, a body region, and a gate. The RFIC also includes a first resistor coupled between a first bias supply and the body region. The RFIC further includes a second resistor coupled between the gate and a second bias supply.

A method of constructing a radio frequency (RF) integrated circuit having a ferroelectric (Fe) field effect transistor (FeFET) is described. The method includes forming a ferroelectric gate stack on a body region of the FeFET. The FeFET has a source region, a drain region, the body region, and a gate. The method also includes fabricating a first resistor coupled between a first bias supply and the body region of the FeFET. The method further includes fabricating a second resistor coupled between a second bias supply the gate of the FeFET.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a wireless device having a wireless local area network module and a radio frequency (RF) front end module for a chipset.

FIG. 2 shows a cross-sectional view of a radio frequency integrated circuit (RFIC), including a switch ferroelectric (Fe) field effect transistor (FeFET).

FIG. 3 is a schematic diagram illustrating a switch ferroelectric (Fe) field effect transistor (FeFET) including a body current bypass resistor for improving a breakdown voltage and harmonic performance, according to aspects of the present disclosure.

FIGS. 4A-4C are schematic diagrams illustrating activation/deactivation of the switch ferroelectric (Fe) field effect transistor (FeFET) of FIG. 3, according to further aspects of the present disclosure.

FIG. 5 is a schematic diagram illustrating a switch product including the set of the ferroelectric (Fe) field effect transistor (FeFETs) of FIGS. 3, 4A, and 4B, according to further aspects of the present disclosure.

FIG. 6 is a process flow diagram illustrating a method of constructing an radio frequency (RF) integrated circuit (RFIC) having a ferroelectric (Fe) field effect transistor (FeFET) including a ferroelectric gate stack, according to aspects of the present disclosure.

FIG. 7 is a block diagram showing an exemplary wireless communication system in which a configuration of the present disclosure may be advantageously employed.

FIG. 8 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described, the use of the term “and/or” is intended to represent an “inclusive OR.” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Transmission frequency specifications of 5G/6G new radio (NR) mandate a substantial transmission frequency increase over current standards for supporting future performance specifications (e.g., transmission rates of ten gigabits per second (10 Gbps)). These massive data transmission rates may be realized with millimeter wave (mmWave) communications that can offer a wider bandwidth. Design challenges for mobile radio frequency (RF) transceivers to meet the 5G/6G NR transmission frequency specifications mandate a substantial transmission frequency increase over current standards. Transistors are generally selected to operate at substantially higher frequencies for supporting these communication enhancements, such as mmWave. These transistors may be switch transistors for implementing an RF switch of a mobile RF transceiver.

For example, high performance complementary metal oxide semiconductor (CMOS) RF switch technologies are currently manufactured to implement switch transistors. An RF front end module (RFFE) may rely on these high performance CMOS RF switch technologies for successful operation. In practice, a series of RF switch transistors may be configured as an RF switch. Unfortunately, gate bias techniques for controlling the series of switch transistors may reduce a switching speed of the RF switch. The reduced switching speed of the RF switch may prohibit meeting 5G and future 6G transmission frequency specifications when implemented in a mobile RF transceiver.

RF switches are used for implementing RFFE products. These RFFE products generally specify a high breakdown voltage and a low on-resistance (Ron)/off-capacitance (RonCoff). In addition, many RFFE products specify the switch to be off when the die is off. A RonCoff value of an RF switch generally provides a figure of merit to rate the performance of an RF switch. The RonCoff value is the product of the Ron and Coff values of the transistor and is used to measure overall switch performance. In practice, RF switches use an electrical input at the gate of the RF transistor to turn “on” or “off.” A positive voltage turns the switch on and a negative voltage turns the switch off. As described, the “on” state of an RF transistor is represented as a resistor and the “off” state as a capacitor.

A low resistance allows more of the signal to travel from one port to another when the switch is on. This metric is called Ron, which is inversely proportional to the width of the transistor. The wider the transistor, the lower the resistance, which allows more of the signal to pass through. A low capacitance will stop more of the signal from traveling from one port to another when the switch is off, which is referred to as Coff. Coff is directly proportional to the width of the transistor. The wider the transistor, the higher the capacitance, and the more the signal leaks through the switch when the switch is off.

The high breakdown voltage specified for the RF switch transistors is a function of an applied negative gate bias and device threshold voltage (Vt). As the threshold voltage Vt increases, the breakdown voltage increases. The increase between the breakdown voltage and the threshold voltage Vt is not symmetric but, rather, is limited by a gate induced drain leakage (GIDL). In addition, the on-resistance of the RF switch transistor decreases as the threshold voltage Vt decreases. In practice, many low on-resistance switch technologies use a threshold voltage Vt below 0 (e.g., close to −1V). Unfortunately, for a switch to be off when the die is off, the threshold voltage Vt exceeds 0 volts (preferably around 0.5 V). As a result, RF switch transistor implementations are forced to sacrifice the on-resistance, the breakdown voltage, or limit the application of the RF switch to meet the specifications.

In practice, the gates of RF switch transistors can be biased to turn the switches off. In order to de-couple a direct current (DC) bias from an RF signal of a mobile RF transceiver, a gate resistor (Rg) is placed in series with the gate. A stacked RF switch may be composed of RF switch transistors that are coupled in series to hold off a larger voltage than a single RF switch transistor is capable of handling. Unfortunately, these gate resistors can significantly affect the signal integrity. In operation, the gate resistors work in parallel as a conductance to ground, which significantly increases dissipative losses in the RF switch stack.

Various aspects of the present disclosure provide techniques for utilization of ferroelectric dielectrics in RF switches for increasing a threshold voltage to enable turning off the RF switch when the die is off. The process flow for semiconductor fabrication of the stacked RF switch may include front-end-of-line (FEOL) processes, middle-of-line (MOL) processes, and back-end-of-line (BEOL) processes. As described, a “ferroelectric gate stack” refers to a crystalline ferroelectric gate dielectric, such as hafnium (Hf)-based gate dielectrics, including hafnium oxide (HfO₂)-based dielectrics. As described, “stacked switches” are switches stacked in series to accommodate a larger voltage than a single switch of the same type will tolerate. As described, “higher voltage” switches are closer to the high voltage source and “lower voltage” switches are closer to the signal termination or ground.

Aspects of the present disclosure relate to ferroelectric dielectrics in RF switches for increasing a threshold voltage to enable turning off the RF switch when the die is off. That is, aspects of the present disclosure employ a ferroelectric gate stack for increasing the threshold voltage, which improves the on-resistance as well as the breakdown voltage of the RF switch. According to this aspect of the present disclosure, an RF integrated circuit (RFIC) includes a switch field effect transistor (FET) having a ferroelectric gate stack, including a source region, a drain region, a body region, and a gate. The RFIC also includes a first resistor coupled between a first bias supply and the body region of the switch FET. The RFIC further includes a second resistor coupled between the gate and a second bias supply.

According to aspects of the present disclosure, altering the threshold voltage Vt improves on resistance (Ron) and (breakdown voltage (Vbd)) of RF switches. For example, a switch-on of a switch transistor is performed by pulsing the switch transistor with a high gate voltage (Vg), or a low body voltage (Vb). Alternatively, the switch-on of the switch transistor is performed by pulsing the switch transistor with a high gate voltage (Vg) together with a low body voltage (Vb). In one configuration, the threshold voltage Vt of a switch transistor is reduced by a first predetermined amount, resulting in a corresponding reduction of the on-resistance by a second predetermined amount. For example, a one-volt (1V) reduction of the threshold voltage Vt provides a corresponding reduction of the on-resistance of approximately ten to twenty percent (e.g., ˜10-20%).

In one configuration, a switch-off of the switch transistor is performed by pulsing the switch transistor with a low gate voltage Vg, or a high body voltage Vb. Alternatively, the switch-off of the switch transistor is performed by pulsing the switch transistor with a low gate voltage Vg together with a high body voltage Vb. In this configuration, the threshold voltage Vt of the switch transistor increase by a first predetermined amount, resulting in a corresponding increase of the breakdown voltage Vbd by a second predetermined amount. For example, a one-volt (1V) increase of the threshold voltage Vt provides a corresponding increase of the breakdown voltage Vbd in the range of approximately one-half volt (0.5 V) to seven tenths of a volt (0.7V), which may be limited by a gate induced drain leakage (GIDL) of the switch transistor.

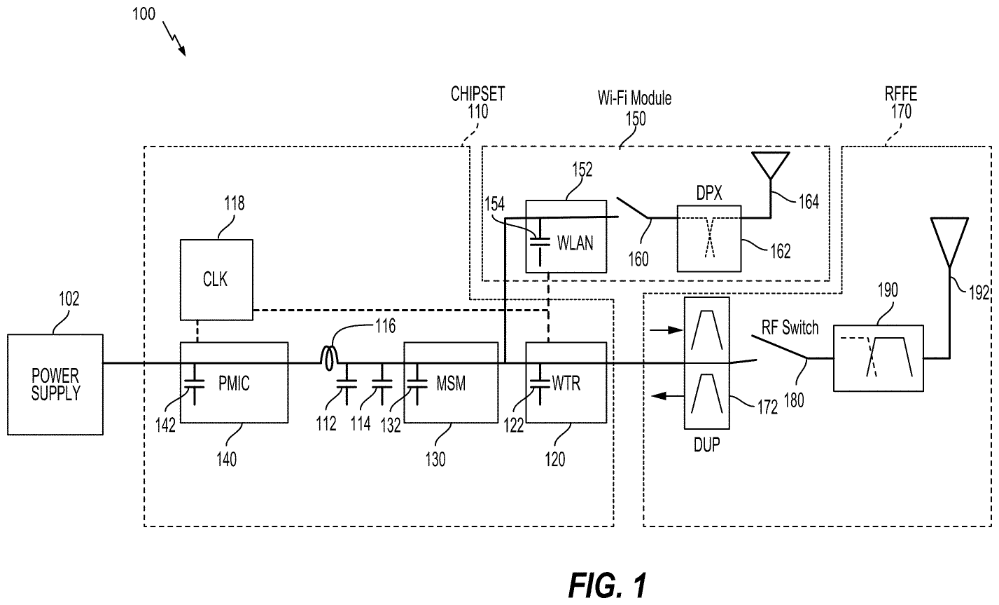

FIG. 1 is a schematic diagram of a wireless device 100 (e.g., a cellular phone or a smartphone), including a radio frequency (RF) switch transistors that include a ferroelectric gate stack. The wireless device 100 has a wireless local area network (WLAN) (e.g., Wi-Fi) module 150 and a radio frequency (RF) front-end module 170 for a chipset 110. The Wi-Fi module 150 includes a first diplexer 162 communicably coupling an antenna 164 to a wireless local area network module (e.g., WLAN module 152). A first RF switch 160 communicably couples the first diplexer 162 to the WLAN module 152. The RF front-end module 170 includes a second diplexer 190 communicably coupling an antenna 192 to the wireless transceiver (WTR) 120 through a duplexer (DUP) 172. A second RF switch 180 communicably couples the second diplexer 190 to the duplexer 172.

The WTR 120 and the WLAN module 152 of the Wi-Fi module 150 are coupled to a modem (MSM, e.g., a baseband modem) 130 that is powered by a power supply 102 through a power management integrated circuit (PMIC) 140. The chipset 110 also includes capacitors 112 and 114, as well as an inductor(s) 116 to provide signal integrity. The PMIC 140, the modem 130, the WTR 120, and the WLAN module 152 each include capacitors (e.g., 142, 132, 122, and 154) and operate according to a clock 118. The geometry and arrangement of the various inductor and capacitor components in the chipset 110 may reduce the electromagnetic coupling between the components.

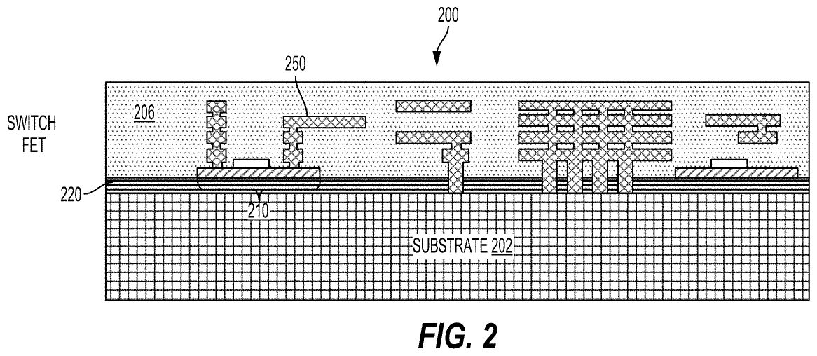

The WTR 120 of the wireless device generally includes a mobile RF transceiver to transmit and receive data for two-way communications. The WTR 120 and the RF front-end module 170 may be implemented using high performance complementary metal oxide semiconductor (CMOS) RF switch technologies to implement switch transistors of the first RF switch 160 and the second RF switch 180. An RF front-end module 170 may rely on these high performance CMOS RF switch technologies for successful operation. In practice, a series of RF switch transistors may be configured as an RF switch. An RF switch transistor is shown in FIG. 2.

FIG. 2 shows a cross-sectional view of a radio frequency (RF) integrated circuit (RFIC) 200. As shown in FIG. 2, the RFIC 200 includes an active device 210 on an insulator layer 220 (e.g., buried oxide (BOX)) supported by a substrate 202 (e.g., a silicon wafer). The RFIC 200 may be fabricated as a complementary metal oxide semiconductor (CMOS) transistor using a CMOS process. The RFIC 200 also includes interconnects 250 coupled to the active device 210 within a first dielectric layer 206. The active device 210 on the insulator layer 220 may be a CMOS transistor. The RF front-end module 170 (of FIG. 1) may rely on these high performance CMOS RF technologies for successful operation. The RF integrated circuit 200 may implement the RF front-end module 170 in FIG. 1. For example, the active device 210 may be a switch field effect transistor (FET) of the first RF switch 160 of the Wi-Fi module 150 and/or the second RF switch 180 of the RF front-end module 170 (as shown in FIG. 1).

The configuration of the RF front-end module 170 may rely on high performance complementary metal oxide semiconductor (CMOS) RF switch technologies. In particular, the RF front-end module 170 may rely on these high performance CMOS RF switch technologies for successful operation of the second RF switch 180 (and/or the first RF switch 160). In practice, a series of RF switch transistors may be configured as an RF switch. Unfortunately, gate bias techniques for controlling the series of switch transistors may reduce a switching speed of the RF switch. The reduced switching speed of the RF switch may prohibit meeting 5G and future 6G transmission frequency specifications when implemented in a mobile RF transceiver.

RF switches are used for implementing RFFE products, such as the RF front-end module 170. These RFFE products generally specify a high breakdown voltage, and a low on-resistance (Ron)/off-capacitance (RonCoff). In addition, many RFFE products specify the switch to be off when the die is off. A RonCoff value of an RF switch generally provides a figure of merit that is used to rate the performance of an RF switch. The RonCoff value is the product of the Ron and Coff values of the transistor and is used to measure overall switch performance. In practice, RF switches use an electrical input at the gate of the RF transistor to turn “on” or “off.” A positive voltage turns the switch on and a negative voltage turns the switch off. As described, the “on” state of an RF transistor is represented as a resistor and the “off” state as a capacitor.

A low resistance allows more of the signal to travel from one port to another when the switch is on. This metric is called Ron, which is inversely proportional to the width of the transistor. The wider the transistor the lower the resistance, which allows more of the signal to get through. A low capacitance will stop more of the signal from traveling from one port to another when the switch is off, which is referred to as Coff. Coff is directly proportional to the width of the transistor. The wider the transistor, the higher the capacitance, and the more the signal leaks through the switch when the switch is off.

The high breakdown voltage specified for the RF switch transistors is a function of an applied negative gate bias and device threshold voltage (Vt). As the threshold voltage Vt increases, the breakdown voltage increases. The increase between the breakdown voltage and the threshold voltage Vt is not symmetric but, rather, is limited by a gate induced drain leakage (GIDL). In addition, the on-resistance of the RF switch transistor decreases as the threshold voltage Vt decreases. In practice, many low on-resistance switch technologies use a threshold voltage Vt below 0 (e.g., close to −1V). Unfortunately, for a switch to be off when the die is off, the threshold voltage Vt exceeds 0 volts (preferably around 0.5 V). As a result, RF switch transistor implementations are forced to sacrifice the on-resistance, the breakdown voltage, or limit the application of the RF switch to meet the specifications.

For example, during an off state, the active device 210 (e.g., a switch field effect transistor (FET)) isolates the RF integrated circuit from an input power (Pin). Isolation of the input power Pin by the active device 210 increases by negatively biasing a gate of the active device 210, for hard turn-off of the active device 210. Unfortunately, negatively biasing the gate of the active device 210 may significantly increase a gate-to-drain voltage (Vgd) of the active device 210. The high gate-to-drain voltage Vgd triggers a gate induced drain leakage (GIDL) current, causing positive charge to accumulate in a body of the active device 210. That is, a high potential difference between the gate and the drain of the switch FET causes the GIDL current.

Furthermore, when an RF signal is received at the drain of the active device 210, that is in the biased off-state, the transmission of the RF signal may be corrupted along the intended path if the active device 210 is not fully isolated. For example, if the gate of the active device 210 fails to isolate the RF signal from, for example, a power supply coupled to the active device 210, the RF signal is significantly corrupted. Isolating the RF signal (e.g., the gate) from a power supply may be referred to as RF isolation.

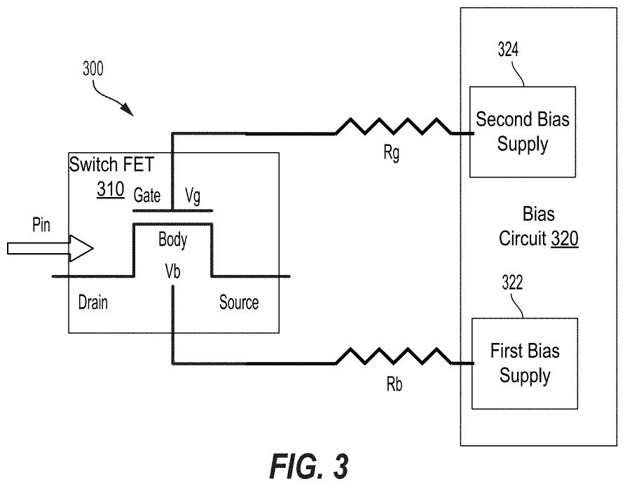

FIG. 3 is a schematic diagram illustrating a radio frequency integrated circuit (RFIC) 300 having a switch ferroelectric (Fe) field effect transistor (FeFET) 310 including a ferroelectric gate stack for improving a breakdown voltage and a threshold voltage, according to aspects of the present disclosure. In this configuration, a body resistor (Rb) is coupled between the body region and a first bias supply 322 of a bias circuit 320 of the RFIC 300. In this example, a gate resistor (Rg) is coupled between the gate and a second bias supply 324 of the bias circuit 320 of the RFIC 300.

This aspect of the present disclosure incorporates a ferroelectric gate dielectric layer in a gate stack of the switch FeFET 310 for increasing a threshold voltage (Vt) to enable turning off the switch FeFET 310 when a die, including the RFIC 300, is off. That is, aspects of the present disclosure employ a ferroelectric gate stack within the switch FeFET 310 for increasing the threshold voltage Vt, which improves the on-resistance (Ron) as well as the breakdown voltage (Vbd) of the switch FeFET 310. In this configuration, the switch FeFET 310 having a ferroelectric gate stack, includes a source region, a drain region, a body region, and a gate. The RFIC 300 also includes a first resistor (e.g., Rb) coupled between the first bias supply 322 and the body region of the switch FeFET 310. The RFIC 300 further includes a second resistor (e.g., Rg) coupled between the gate and the second bias supply of the bias circuit 320. Although shown as a single bias circuit, in one configuration, the RFIC 300 includes a first bias circuit and a second bias circuit.

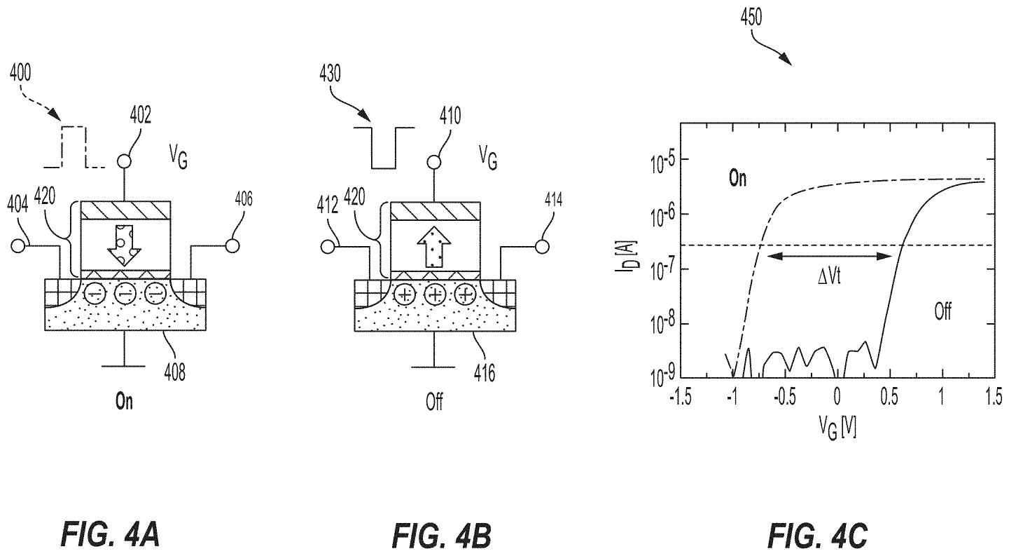

FIGS. 4A-4C are schematic diagrams illustrating activation/deactivation of the switch FeFET 310 of FIG. 3, according to aspects of the present disclosure. According to aspects of the present disclosure, altering the threshold voltage Vt improves an on resistance (Ron) and a breakdown voltage (Vbd) of the switch FET 310. In this example, the switch FeFET 310 is shown with a gate terminal 402, a drain terminal 404, a source terminal 406, and a body 408. Aspects of the present disclosure rely on crystalline ferroelectric gate dielectrics to form a ferroelectric gate stack 420 of the switch FeFET 310. In one configuration, the ferroelectric gate stack 420 of the switch FeFET 310 is fabricated using a crystalline hafnium oxide (HfO₂)-based dielectric to form a ferroelectric gate dielectric layer on an oxide layer (e.g., silicon oxynitride (SiON)) on a body 408 of the switch FeFET 310. The ferroelectric gate stack 420 may include a contact layer (e.g., titanium nitride (TiN)) on the ferroelectric gate dielectric layer.

Although described with reference to HfO₂-based dielectrics, other ferroelectric dielectrics (e.g., aluminum oxide (AlOx)) are also contemplated. One configuration of a gate stack structure of a switch FeFET includes doped HfO₂, which may be a zirconium-doped hafnium oxide (Zr:HfO₂), a silicon-doped hafnium oxide (Si:HfO₂) dielectric layer or an indium selenide (α-In₂Se₃) could also be used). A thickness of this ferroelectric gate dielectric is application-dependent. For example, to ensure switching does not happen in case a high RF pulse is applied to the switch FeFET, a dielectric thickness of the ferroelectric gate dielectric layer may be in the range of approximately two (2) nanometers (˜20 Angstroms) to thirty nanometers (˜30 nm). Aspects of the present disclosure recognize that too thick of the ferroelectric gate dielectric (e.g., HfO₂) layer could result in loss of the ferroelectric properties.

As shown in FIG. 4A, a switch-on of the switch FeFET 310 is performed by pulsing the switch FeFET 310 with a high voltage pulse 400 (e.g., a high gate voltage (Vg), or a low body voltage (Vb). Alternatively, the switch-on of the switch FeFET 310 is performed by pulsing the switch FeFET 310 with the high voltage pulse 400 (e.g., a high gate voltage Vg) together with the low body voltage Vb. In one configuration, the threshold voltage Vt of the switch FeFET 310 reduces by a first predetermined amount, resulting in a corresponding reduction of the on-resistance by a second predetermined amount. For example, a one-volt (1V) reduction of the threshold voltage Vt provides a corresponding reduction of the on-resistance of approximately ten to twenty percent (e.g., ˜10-20%).

As shown in FIG. 4B, a switch-off of the switch FET 310 is performed by pulsing the switch FET 310 with a low voltage pulse 430 (e.g., a low gate voltage Vg), or a high body voltage Vb. Alternatively, the switch-off of the switch FET 310 is performed by pulsing the switch FET with the low voltage pulse 430 (e.g., a low gate voltage Vg) together with the high body voltage Vb. In this configuration, the threshold voltage Vt of the switch FET increases by a first predetermined amount, resulting in a corresponding increase of the breakdown voltage Vbd by a second predetermined amount. For example, a one-volt (1V) increase of the threshold voltage Vt provides a corresponding increase of the breakdown voltage Vbd in the range of approximately one-half volt (0.5 V) to seven tenths of a volt (0.7V), which may be limited by a gate induced drain leakage (GIDL) of the switch FeFET 310.

FIG. 4C is a graph 450 illustrating a threshold voltage difference of the switch FeFET 310 including the ferroelectric gate stack 420, according to aspects of the present disclosure. In this example, the graph 450 is a current versus voltage graph, having the gate voltage Vg as the x-axis and a drain current Id as the y-axis. The graph 450 illustrates approximately a one and a half (1.5) threshold voltage difference between the switch-on state shown in FIG. 4A and the switch-off state shown in FIG. 4B.

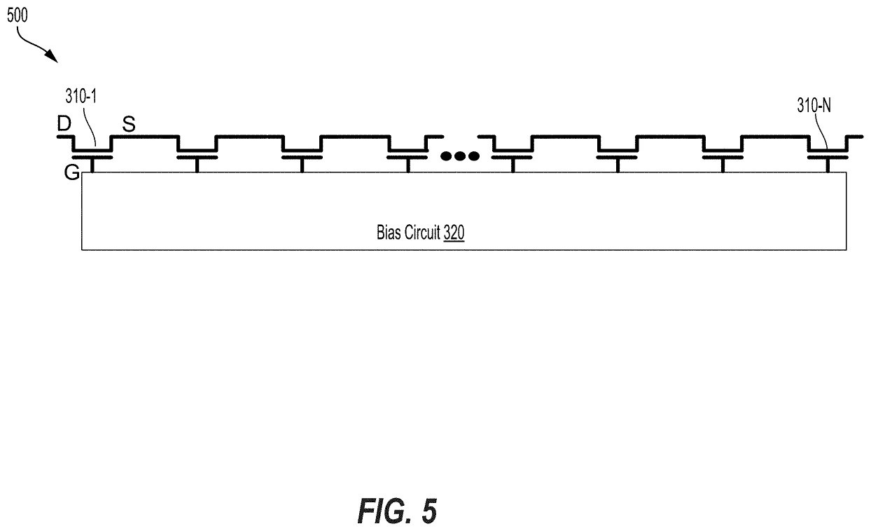

FIG. 5 is a schematic diagram illustrating a stacked radio frequency (RF) switch 500 including the switch FeFET 310 (310-1, . . . , 310-N) of FIGS. 3, 4A, and 4B, according to further aspects of the present disclosure. In this configuration, the stacked RF switch 500 is composed of the switch FeFETs 310 coupled in series to hold off a larger voltage than a single switch FET is capable of handling. The stacked RF switch 500 also includes the bias circuit 320 of FIG. 3, which may be implemented using multiple ones of the bias circuit. In this simplified version, a connection between the body of the switch FeFET 310 and the bias circuit 320 is not shown. This connection may be performed as shown in the FeFET configuration of FIG. 3.

Various aspects of the present disclosure provide techniques for improving a breakdown voltage and a threshold voltage of the switch FeFET 310, by using a ferroelectric gate stack, as shown in FIGS. 4A and 4B. In one configuration, the threshold voltage Vt of the switch FeFET 310 reduces by a first predetermined amount, resulting in a corresponding reduction of the on-resistance by a second predetermined amount. For example, a one-volt (1V) reduction of the threshold voltage Vt provides a corresponding reduction of the on-resistance of approximately ten to twenty percent (e.g., ˜10-20%).

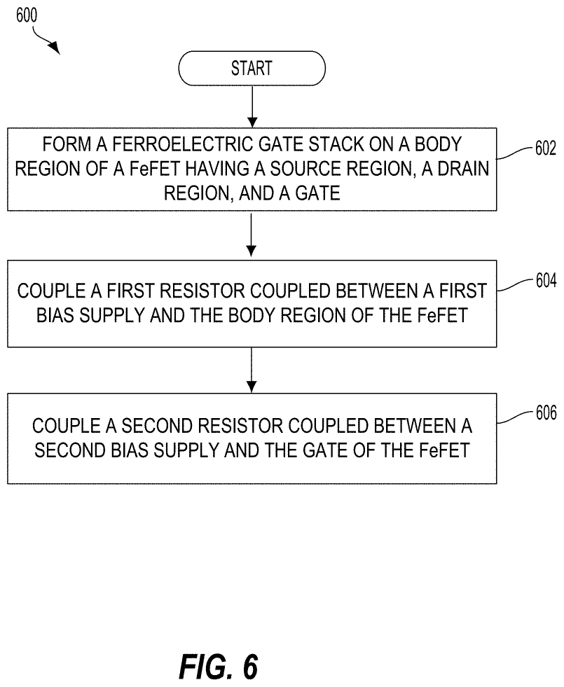

In one configuration, the threshold voltage Vt of the switch FeFET 310 increases by a first predetermined amount, resulting in a corresponding increase of the breakdown voltage Vbd by a second predetermined amount. For example, a one-volt (1V) increase of the threshold voltage Vt provides a corresponding increase of the breakdown voltage Vbd in the range of approximately one-half volt (0.5 V) to seven tenths of a volt (0.7V), which may be limited by a gate induced drain leakage (GIDL) of the switch FeFET 310. A method of constructing an RFIC having the switch FeFET 310 having a ferroelectric gate stack, according to aspects of the present disclosure, is shown in FIG. 6.

FIG. 6 is a process flow diagram illustrating a method for constructing a radio frequency (RF) integrated circuit (RFIC) having a ferroelectric (Fe) field effect transistor (FeFET), according to an aspect of the present disclosure. A method 600 begins in block 602, in which a ferroelectric gate stack is formed on a body region of the FeFET. The FeFET has a source region, a drain region, and a gate. For example, as shown in FIGS. 4A and 4B, the ferroelectric gate stack 420 of the switch FeFET 310 is fabricated using a crystalline hafnium oxide (HfO₂)-based dielectric to form a ferroelectric gate dielectric layer on an oxide layer (e.g., silicon oxynitride (SiON)) on a body 408 of the switch FeFET 310. The ferroelectric gate stack 420 may include a contact layer (e.g., titanium nitride (TiN)) on the ferroelectric gate dielectric layer.

As further shown in FIG. 6, in block 604, a first resistor is coupled between a first bias supply and the body region of the FeFET. For example, as shown in FIG. 3, a body resistor (Rb) is coupled between the body region and a first bias supply 322 of a bias circuit 320 of the RFIC 300. The method 600 may further include coupling a second resistor between a second bias supply and the gate of the FeFET. For example, as shown in FIG. 3, the RFIC 300 includes a second resistor (Rg) coupled between the gate and the second bias supply of the bias circuit 320.

Aspects of the present disclosure relay on crystalline ferroelectric gate dielectrics to form a switch ferroelectric (Fe) FET (FeFET). In one configuration, a gate stack of the FeFET may be fabricated using crystalline hafnium oxide (HfO₂)-based dielectrics to form ferroelectric gate dielectrics. Although described with reference to HfO₂-based dielectrics, other ferroelectric dielectrics (e.g., aluminum oxide (AlOx)) are also contemplated. In one configuration of a gate stack structure of a switch FeFET includes doped HfO₂, which may be a zirconium-doped (Zr:HfO₂) or a silicon-doped (Si:HfO₂) dielectric layer. A thickness of this ferroelectric gate dielectric is application-dependent. For example, to ensure switching does not happen in case a high RF pulse is applied to the switch FeFET, the thickness of the ferroelectric gate dielectric may be approximately thirty nanometers (˜30 nm). Aspects of the present disclosure recognize that too thick of the ferroelectric gate dielectric (e.g., HfO₂) layer could result in loss of the ferroelectric properties.

According to a further aspect of the present disclosure, a radio frequency (RF) front-end circuit includes a switch field effect transistor (FET) is described. The switch FET is composed of a ferroelectric gate stack having a source region, a drain region, a body region, and a gate. The RF front-end circuit includes a first resistor coupled between a first bias supply and the body region. The RF front-end circuit also includes a second resistor coupled between the gate and a second bias supply. The RF front-end circuit further includes means for biasing through the first bias supply coupled to the body region of the switch FET and through the second bias supply coupled to the gate of the switch FET. The biasing means may be the bias circuit 320, shown in FIG. 3. In another aspect, the aforementioned means may be any module or any apparatus configured to perform the functions recited by the aforementioned means.

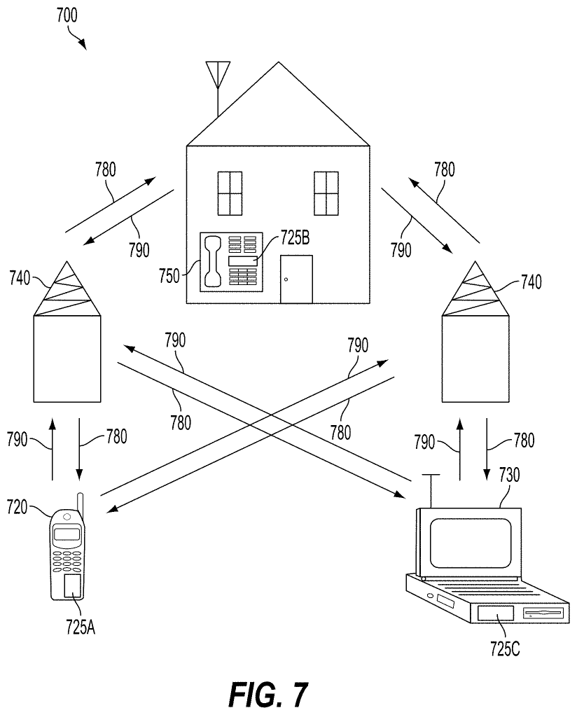

FIG. 7 is a block diagram showing an exemplary wireless communication system 700 in which an aspect of the present disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include IC devices 725A, 725C, and 725B that include the disclosed RFIC. It will be recognized that other devices may also include the disclosed RFIC, such as the base stations, switching devices, and network equipment. FIG. 7 shows forward link signals 780 from the base station 740 to the remote units 720, 730, and 750 and reverse link signals 790 from the remote units 720, 730, and 750 to base stations 740.

In FIG. 7, remote unit 720 is shown as a mobile telephone, remote unit 730 is shown as a portable computer, and remote unit 750 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 7 illustrates remote units, according to the aspects of the present disclosure, the present disclosure is not limited to these exemplary illustrated units. Aspects of the present disclosure may be suitably employed in many devices, which include the disclosed RFIC.

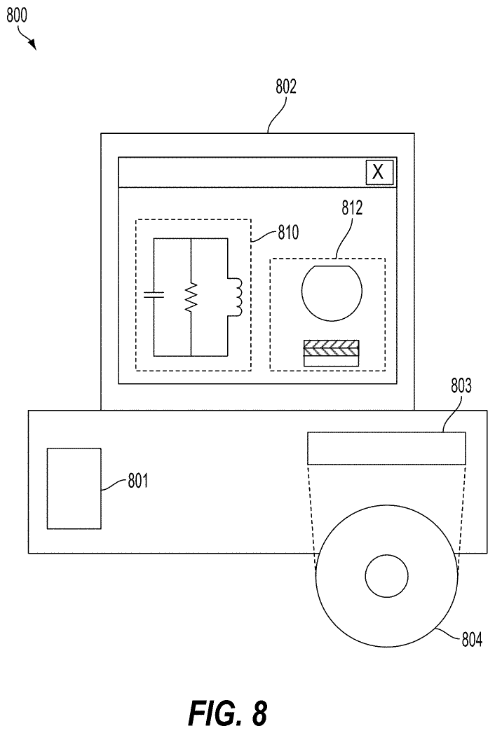

FIG. 8 is a block diagram illustrating a design workstation used for circuit, layout, and logic design of a semiconductor component, such as the RF devices disclosed above. A design workstation 800 includes a hard disk 801 containing operating system software, support files, and design software such as Cadence or OrCAD. The design workstation 800 also includes a display 802 to facilitate a circuit design 810 or an RFIC 812. A storage medium 804 is provided for tangibly storing the circuit design 810 or the RFIC 812. The circuit design 810 or the RFIC 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit design 810 or the RFIC 812 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described herein may be utilized, according to the present disclosure. Accordingly, the appended claims are intended to include within their scope such processes, machines, manufacture, compositions of matter, means, methods, or steps.

What is claimed is:

1. A radio frequency integrated circuit (RFIC), comprising:
a field effect transistor (FET) including a ferroelectric gate stack having a source region, a drain region, a body region, and a gate;
a first resistor coupled between a first bias supply and the body region; and
a second resistor coupled between the gate and a second bias supply.

2. The RFIC of claim 1, further comprising a bias circuit including the first bias supply coupled to the body region of the FET through the first resistor, and the second bias supply coupled to the gate of the FET through the second resistor.

3. The RFIC of claim 1, in which the ferroelectric gate stack comprises:
an oxide layer on the body region of the FET;
a ferroelectric gate dielectric layer on the oxide layer; and
a contact layer on the ferroelectric gate dielectric layer.

4. The RFIC of claim 3, in which the ferroelectric gate dielectric layer comprises a silicon-doped hafnium oxide (Si:HfO₂) layer.

5. The RFIC of claim 3, in which the ferroelectric gate dielectric layer comprises a zirconium-doped hafnium oxide (Zr:HfO₂) layer.

6. The RFIC of claim 3, in which the ferroelectric gate dielectric layer comprises an indium selenide (α-In₂Se₃) layer.

7. The RFIC of claim 3, in which a thickness of the ferroelectric gate dielectric layer is in a range of one (1) nanometer to eighty (80) nanometers.

8. The RFIC of claim 1, in which a threshold voltage (Vt) of the FET is greater than zero.

9. The RFIC of claim 1, further comprising:
a first bias circuit having the first bias supply coupled to the body region of the FET through the first resistor; and
a second bias circuit having the second bias supply coupled to the gate of the FET through the second resistor.

10. The RFIC of claim 1, integrated into a radio frequency (RF) front end module, the RF front end module incorporated into at least one of a music player, a video player, an entertainment unit, a navigation device, a communications device, a personal digital assistant (PDA), a fixed location data unit, a mobile phone, and a portable computer.

11. A method of constructing a radio frequency (RF) integrated circuit having a ferroelectric (Fe) field effect transistor (FeFET), comprising:
forming a ferroelectric gate stack on a body region of the FeFET, the FeFET having a source region, a drain region, the body region, and a gate;
coupling a first resistor between a first bias supply and the body region of the FeFET; and
coupling a second resistor between a second bias supply and the gate of the FeFET.

12. The method of claim 11, further comprising forming a bias circuit including the first bias supply coupled to the body region of the FeFET through the first resistor, and the second bias supply coupled to the gate of the FeFET through the second resistor.

13. The method of claim 11, in which forming the ferroelectric gate stack comprises:
depositing an oxide layer on the body region of the FeFET;
depositing a ferroelectric gate dielectric layer on the oxide layer; and
depositing a contact layer on the ferroelectric gate dielectric layer.

14. The method of claim 13, in which depositing the ferroelectric gate dielectric layer comprises depositing a silicon-doped hafnium oxide (Si:HfO₂) layer.

15. The method of claim 13, in which depositing the ferroelectric gate dielectric layer comprises depositing a zirconium-doped hafnium oxide (Zr:HfO₂) layer.

16. The method of claim 13, in which depositing the ferroelectric gate dielectric layer comprises depositing an indium selenide (α-In₂Se₃) layer.

17. The method of claim 13, in which depositing the ferroelectric gate dielectric layer comprises depositing the ferroelectric gate dielectric layer having a thickness in a range of one (1) nanometer to eighty (80) nanometers.

18. The method of claim 13, in which depositing the contact layer comprises depositing a titanium nitride (TiN) layer on the ferroelectric gate dielectric layer.

19. The method of claim 11, in which a threshold voltage (Vt) of the FeFET is greater than zero.

20. The method of claim 11, further comprising integrating the RF integrated circuit having the FeFET into a radio frequency (RF) front end module, the RF front end module incorporated into at least one of a music player, a video player, an entertainment unit, a navigation device, a communications device, a personal digital assistant (PDA), a fixed location data unit, a mobile phone, and a portable computer.
